(19) United States
(12) Patent Application Publication
(10) Pub. No.: US 2024/0379717 A1
(43) Pub. Date: Nov. 14, 2024

(54) IMAGE SENSOR AND METHOD OF FABRICATING THE SAME

(71) Applicant: SAMSUNG ELECTRONICS CO., LTD., Suwon-si (KR)

(72) Inventor: Kook Tae KIM, Suwon-si (KR)

(73) Assignee: SAMSUNG ELECTRONICS CO., LTD., Suwon-si (KR)

(21) Appl. No.: 18/516,097

(22) Filed: Nov. 21, 2023

(30) Foreign Application Priority Data
May 11, 2023 (KR) 10-2023-0061356

(51) Int. Cl. H01L 27/146

(52) U.S. Cl. CPC H01L 27/14636; H01L 27/14645; H01L 27/14698

(57) ABSTRACT

An image sensor includes a first chip; a second chip stacked on the first chip; and a bonding portion provided between the first chip and the second chip, wherein the first chip includes: a first semiconductor substrate including a first surface and a second surface opposing the first surface; a photoelectric conversion region in the first semiconductor substrate; and a first circuit interconnection layer provided on the first surface and adjacent to the photoelectric conversion region, wherein the second chip includes: a second semiconductor substrate including a third surface and a fourth surface facing the first surface and opposing the third surface; and a second circuit interconnection layer provided on the fourth surface, and wherein the bonding portion includes: a bonding layer provided between the first circuit interconnection layer and the second circuit interconnection layer and configured to connect the first chip and the second chip; and a diffusion barrier layer provided between the second circuit interconnection layer and the bonding layer and configured to inhibit diffusion of at least one of hydrogen or deuterium.

### CROSS-REFERENCE TO RELATED APPLICATION

This application claims priority to Korean Patent Application No. 10-2023-0061356, filed on May 11, 2023, in the Korean Intellectual Property Office, the disclosure of which is incorporated by reference herein in its entirety.

### BACKGROUND

The present disclosure relates to an image sensor and a method of fabricating the same.

An image sensing device may include semiconductor elements, which may convert optical information into an electric signal. Such an image sensing device may include a charge coupled device (CCD) image sensing device and a complementary metal-oxide semiconductor (CMOS) image sensing device.

The CMOS image sensor may be abbreviated as a “CIS.” The CIS may include a plurality of pixels arranged two-dimensionally. Each of the pixels may include, for example, a photodiode (PD). The photodiode may serve to convert incident light into an electric signal.

Such a CMOS image sensor may involve a high-pressure annealing process during a fabrication process. In this case, a logic circuit may be deteriorated due to diffusion of impurities in the sensor.

### SUMMARY

One or more example embodiments provide an image sensor which may have improved electrical characteristics without deterioration of elements in a logic circuit.

According to an aspect of the disclosure, an image sensor includes: a first chip; a second chip stacked on the first chip; and a bonding portion provided between the first chip and the second chip, wherein the first chip includes: a first semiconductor substrate including a first surface and a second surface opposing the first surface: a photoelectric conversion region in the first semiconductor substrate; and a first circuit interconnection layer provided on the first surface and adjacent to the photoelectric conversion region, wherein the second chip includes: a second semiconductor substrate including a third surface and a fourth surface facing the first surface and opposing the third surface; and a second circuit interconnection layer provided on the fourth surface, and wherein the bonding portion includes: a bonding layer provided between the first circuit interconnection layer and the second circuit interconnection layer and configured to connect the first chip and the second chip; and a diffusion barrier layer provided between the second circuit interconnection layer and the bonding layer and configured to inhibit diffusion of at least one of hydrogen or deuterium.

According to an aspect of the disclosure, a method of fabricating an image sensor includes: forming a portion of a pixel and a first circuit interconnection layer on a first semiconductor substrate including a first surface and a second surface opposing the first surface; forming a second circuit interconnection layer on a second semiconductor substrate including a third surface and a fourth surface opposing the third surface; forming a diffusion barrier layer on at least one of the first circuit interconnection layer or the second circuit interconnection layer: forming a first bonding layer on the first circuit interconnection layer; forming a second bonding layer on the second circuit interconnection layer; providing the first surface to oppose the third surface and then connecting the first bonding layer and the second bonding layer; planarizing the second surface: performing at least one of a hydrogen treatment or a deuterium treatment in a direction extending from the second surface to the first surface; and forming portions of the pixel, other than the portion of the pixel, on the second surface.

According to an aspect of the disclosure, a method of fabricating an image sensor, includes: forming a first chip including a first semiconductor substrate and first elements of a pixel: forming a second chip to control the first chip: forming a diffusion barrier layer on at least one of an upper surface of the first chip or an upper surface of the second chip; bonding the first chip and the second chip with the diffusion barrier layer interposed between the first chip and the second chip: planarizing an external side surface of the first chip; performing a hydrogen treatment or a deuterium treatment on the first chip in a direction extending from the first chip to the second chip; and forming second elements of the pixel, which are different from the first elements of the pixel, on the external side surface of the first chip.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a block diagram of an image sensor according to one or more example embodiments:

FIGS. 2A and 2B are circuit diagrams of pixels in an image sensor according to one or more example embodiments:

FIGS. 3A and 3B are conceptual diagrams illustrating a layout of an image sensor according to one or more example embodiments:

FIG. 4A is a plan view illustrating an image sensor according to one or more example embodiments, and FIG. 4B is a cross-sectional view taken along line A-A′ of FIG. 4A, according to one or more example embodiments:

FIG. 5A is a diagram illustrating a bonding portion in FIG. 4B in detail and is an enlarged cross-sectional view of portion P1 of FIG. 4B, according to one or more example embodiments, and FIG. 5B is an enlarged view of a diffusion barrier layer of FIG. 5A according to one or more example embodiments:

FIGS. 6A, 6B, 6C and 6D are cross-sectional views illustrating diffusion barrier layers according to one or more example embodiments:

FIGS. 7A, 7B, 7C and 7D are cross-sectional views illustrating diffusion barrier layers according to one or more example embodiments:

FIGS. 8A and 8B are cross-sectional views illustrating diffusion barrier layers according to one or more example embodiments;

FIG. 9 is a cross-sectional view illustrating a diffusion barrier layer according to one or more example embodiments; and

FIGS. 10A, 10B, 10C, 10D, 10E, 10F, 10G, 10H, 10I and 10J are cross-sectional views illustrating a method of fabricating an image sensor according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

The present disclosure may be modified in various ways, and may have various embodiments, among which specific embodiments will be described in detail with reference to the accompanying drawings. However, it will be apparent to those skilled in the art that the description of the specific embodiments of the present disclosure is not intended to limit the present disclosure to a particular mode of practice, and that the present disclosure may include all modifications, equivalents, and substitutes included in the spirit and technical scope of the present disclosure.

One or more example embodiments relate to a stacked image sensor, in which a plurality of chips, for example, a sensor chip and a logic chip overlap each other, including a diffusion barrier layer preventing hydrogen and/or deuterium from diffusing into elements of a logic chip.

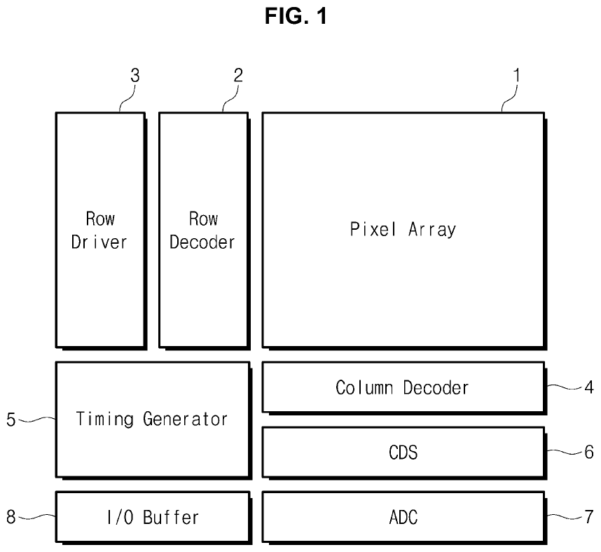

FIG. 1 is a block diagram of an image sensor according to one or more example embodiments.

Referring to FIG. 1, an image sensor according to one or more example embodiments may include a pixel array 1, a row decoder 2, a row driver 3, a column decoder 4, a timing generator 5, a correlated double sampler (CDS) 6, an analog-to-digital converter (ADC) 7, and an input/output buffer (I/O buffer) 8.

The pixel array 1 may include a plurality of unit pixels arranged two-dimensionally, and may convert an optical signal into an electrical signal. The pixel array 1 may be driven by a plurality of driving signals such as a pixel select signal, a reset signal, and a charge transfer signal from the row driver 3. The converted electrical signal may be provided to the correlated double sampler 6.

The row driver 3 may provide a plurality of driving signals for driving a plurality of unit pixels to the pixel array 1 based on a result decoded by the row decoder 2. When unit pixels are arranged in a matrix, driving signals may be provided for each row.

The timing generator 5 may provide a timing signal and a control signal to row decoder 2 and column decoder 4.

The correlated double sampler 6 may receive the electrical signal generated by the pixel array 1, and may hold and sample the received electrical signal. The correlated double sampler 6 may double-sample a specific noise level and a signal level of the electrical signal to output a difference level corresponding to a difference between the noise level and the signal level.

The analog-to-digital converter 7 may convert an analog signal, corresponding to the difference level output from the correlated double sampler 6, into a digital signal and then output the digital signal.

The input/output buffer 8 may latch digital signals, and the latched digital signals may be sequentially output to an image signal processing unit based on results decoded by the column decoder 4.

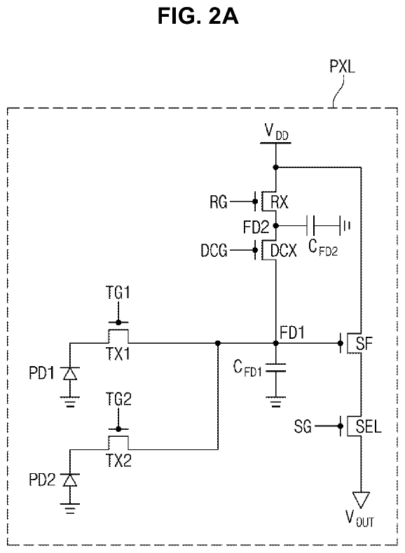

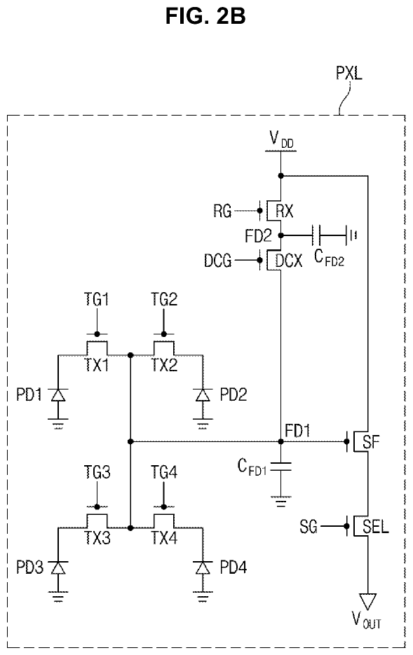

FIGS. 2A and 2B are circuit diagrams of pixels in an image sensor according to one or more example embodiments. The circuit diagrams of the pixels are provided as an example, and various modifications may be made within the scope of the present disclosure.

Referring to FIG. 2A, a pixel PXL may include a plurality of photoelectric conversion elements PD1 and PD2, a plurality of transfer transistors TX1 and TX2, a first floating diffusion region FD1 and a second floating diffusion region FD2, and a plurality of pixel transistors.

In one or more example embodiments, the pixel PXL may include a first floating diffusion region FD1, commonly connected to first and second photoelectric conversion elements PD1 and PD2, and first and second transfer transistors TX1 and TX2.

The pixel transistors may include a reset transistor RX, a source follower transistor SF, a select transistor SEL, and a dual conversion gain transistor DCX. In one or more example embodiments, each pixel PXL has been described as including four pixel transistors. However, embodiments are not limited thereto, and the number of pixel transistors in each pixel PXL may vary.

For example, the first and second photoelectric conversion elements PD1 and PD2 may generate and accumulate charges corresponding to incident light. The first and second photoelectric conversion elements PD1 and PD2 may include, for example, a photodiode, a phototransistor, a photogate, a pinned photodiode (PPD), or combinations thereof.

The first and second transfer transistors TX1 and TX2 may transfer the charges, accumulated in the first and second photoelectric conversion elements PD1 and PD2, to the first floating diffusion region FD1. The first and second transfer transistors TX1 and TX2 may be controlled by the first and second transfer signals TG1 and TG2. The first and second transfer transistors TX1 and TX2 may share the first floating diffusion region FD1.

The first floating diffusion region FD1 may receive and cumulatively store the charges generated by the first and/or second photoelectric conversion elements PD1 and PD2. The source follower transistor SF may be controlled depending on the amount of photocharges accumulated in the first floating diffusion region FD1.

The reset transistor RX may periodically reset the charges accumulated in the first and second floating diffusion regions FD1 and FD2 according to a reset signal applied to the reset gate electrode RG. For example, a drain terminal of the reset transistor RX may be connected to the dual conversion gain transistor DCX, and a source terminal of the reset transistor RX may be connected to the pixel power supply voltage VDD. When the reset transistor RX and the dual conversion gain transistor DCX are turned on, a pixel power supply voltage VDD may be transmitted to the first and second floating diffusion regions FD1 and FD2. Accordingly, the charges accumulated in the first and second floating diffusion regions FD1 and FD2 may be discharged to reset the first and second floating diffusion regions FD1 and FD2.

The dual conversion gain transistor DCX may be connected between the first floating diffusion region FD1 and the second floating diffusion region FD2. The dual conversion gain transistor DCX may be connected in series to the reset transistor RX through the second floating diffusion region FD2. For example, the dual conversion gain transistor DCX may be connected between the first floating diffusion region FD1 and the reset transistor RX. The dual conversion gain transistor DCX may vary capacitance C_{FD1} of the first floating diffusion region FD1 in response to a dual conversion gain control signal to vary a conversion gain of the pixel PXL.

For example, when an image is captured, low-illuminance light and high-illuminance light may be simultaneously incident to a pixel array, or high-intensity light and low-intensity light may be simultaneously incident to the pixel array. Accordingly, each pixel may have a conversion gain, variable depending on incident light. For example, when the dual conversion gain transistor DCX is turned off, a unit pixel may have a first conversion gain. On the other hand, when the dual conversion gain transistor DCX is tumed on, the unit pixel may have a second conversion gain, greater than the first conversion gain. For example, different conversion gains may be provided in a first conversion gain mode (or a high-illuminance mode) and a second conversion gain mode (or a low-illuminance mode) according to the operation of the dual conversion gain transistor DCX.

When the dual conversion gain transistor DCX is turned off, capacitance of the first floating diffusion region FD1 may correspond to the first capacitance C_{FD1}. When the dual conversion gain transistor DCX is turned on, the first floating diffusion region FD1 may be connected to the second floating diffusion region FD2, and thus capacitance in the first and second floating diffusion regions FD1 and FD2 may be equal to a sum of the first and second capacitances C_{FD1} and C_{FD2}. For example, when the dual conversion gain transistor DCX is turned on, the capacitance of the first or second floating diffusion region FD1 or FD2 may be increased to reduce a conversion gain. On the other hand, when the dual conversion gain transistor DCX is turned off, the capacitance of the first floating diffusion region FD1 may be decreased to increase a conversion gain.

The source follower transistor SF may be a source follower buffer amplifier generating source-drain current in proportion to the amount of charges of the first floating diffusion region FD1 input to a source follower gate electrode. The source follower transistor SF may amplify a potential change in the floating diffusion region FD, and may output an amplified signal to an output line Vour through the select transistor SEL. A source terminal of the source follower transistor SF may be connected to a power supply voltage VDD, and a drain terminal of the source follower transistor SF may be connected to a source terminal of the select transistor SEL.

The select transistor SEL may select unit pixels P to be read in units of rows. When the select transistor SEL is turned on by a select signal SG applied a select gate electrode, an electrical signal output to a drain electrode of the source follower transistor SF may be output to the output line VOUT.

Referring to FIG. 2B, a pixel PXL may include first, second, third, and fourth photoelectric conversion elements PD1, PD2, PD3, and PD4, first, second, third, and fourth transfer transistors TX1, TX2, TX3, and TX4, and a first floating diffusion region FD1. Also, the pixel PXL may include four pixel transistors RX, DCX, SF, and SEL, similar to the example embodiment of FIG. 2A.

The first, second, third, and fourth transfer transistors TX1, TX2, TX3, and TX4 may share the first floating diffusion region FD1. Transfer gate electrodes of the first, second, third, and fourth transfer transistors TX1, TX2, TX3, and TX4 may be controlled by the first, second, third, and fourth transfer signals TG1, TG2, TG3, and TG4, respectively.

An image sensor according to one or more example embodiments may be provided with a stack of at least two chips.

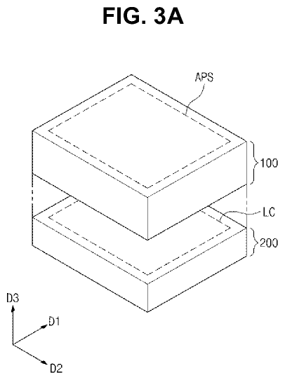

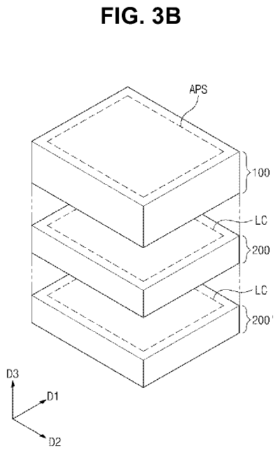

FIGS. 3A and 3B are conceptual diagrams illustrating a layout of an image sensor according to one or more example embodiments.

The image sensor may include a plurality of chips sequentially stacked in one direction. For example, the image sensor may include stacked first chip 100 and second chip 200 stacked as illustrated in FIG. 3A, or first, second, and third chips 100, 200, and 200′ stacked as illustrated in FIG. 3B. In FIG. 3A, the first chip 100 may be an upper chip and the second chip 200 may be a lower chip. In FIG. 3B, the first chip 100 may be an upper chip, the second chip 200 may be an intermediate chip, and the third chip 200′ may be a lower chip. A bonding portion may be provided between two adjacent chips to bond the two adjacent chips to each other. Hereinafter, a direction in which the second chip 200 and the first chip 100 are stacked will be defined as a third direction D3, and two directions intersecting each other on a plane perpendicular to the third direction D3 will be defined as a first direction D1 and a second direction D2. However, the first, second, and third directions D1, D2, and D3 are relative directions defined for ease of description, and may be defined to be different from those of an actual object.

The first chip 100 may be a sensor chip. A plurality of pixels may be arranged in a two-dimensional array structure on the first chip 100, and the first chip 100 may have a pixel array region APS.

A logic circuit may be mounted on the second chip 200 and/or the third chip 200′. The second chip 200 and/or the third chip 200′ may include a logic circuit region LC. Logic circuits may be provided in the logic circuit region LC of the second chip 200 and/or the third chip 200′. The logic circuits may include circuits for processing pixel signals from pixels. For example, the logic circuits may include control a register block, a timing generator, a row driver, a readout circuit, a ramp signal generator, or the like. The second chip 200 may allow a pixel signal, transmitted from the first chip 100, to be transmitted to the logic circuit regions LC of the second chip 200 and the third chip 200′.

A memory device may be further provided in the second chip 200 and/or the third chip 200′. As the memory device, a dynamic random access memory (DRAM) device, a static random access memory (SRAM) device, a spin-transfer torque magnetic random access memory (STT-MRAM) device, or a flash memory device may be provided in an embedded form. The image sensor may temporarily store a frame image using such a memory device and may perform signal processing to significantly reduce a zello effect, resulting in improved operation characteristics of the image sensor. In addition, the memory device of the image sensor may be provided together with the logic devices in an embedded form to simplify a fabrication process and to reduce a size of a product.

Hereinafter, for ease of description, an image sensor including a first chip and a second chip sequentially stacked as illustrated in FIG. 3A will be described. However, embodiments are not limited thereto, and may be applied to an image sensor including three or more chips sequentially stacked.

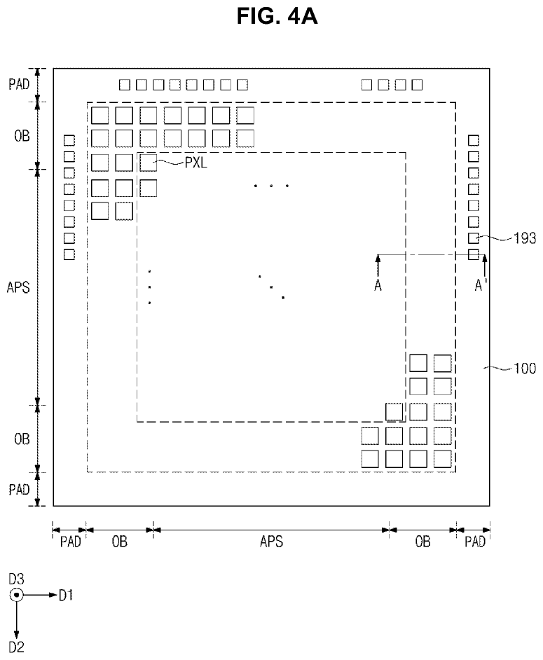

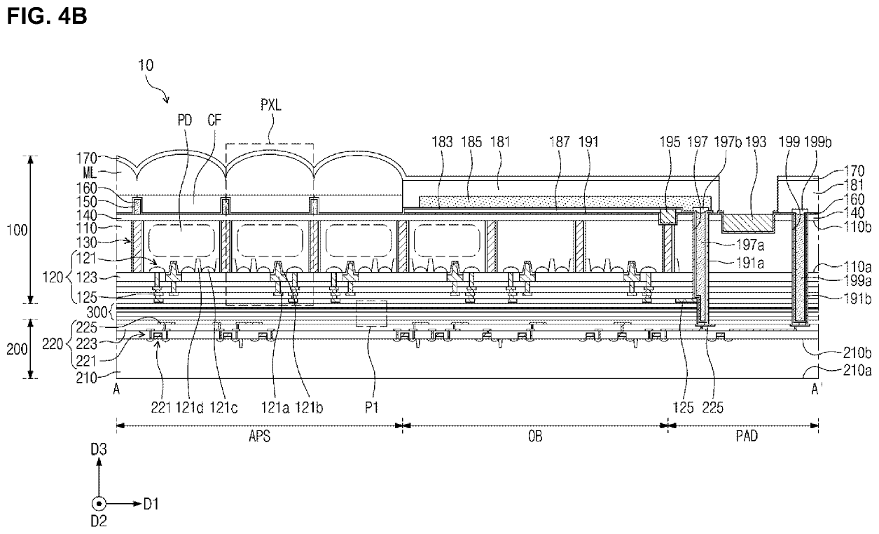

FIG. 4A is a plan view illustrating an image sensor according to one or more example embodiments, and FIG. 4B is a cross-sectional view taken along line A-A′ of FIG. 4A.

Referring to FIGS. 4A and 4B, an image sensor may include a first chip 100 as a sensor chip, a second chip 200 as a logic chip, and a bonding portion 300 provided between the first chip 100 and the second chip 200 to connect the first chip 100 and the second chip 200 to each other. A portion of the bonding portion 300 may be provided to the first chip 100, and another portion of the bonding portion 300 may be provided to the second chip 200. However, according to one or more example embodiments, the bonding portion 300 will be described as an additional component for ease of description.

The first chip 100 may include a first semiconductor substrate 110, a first circuit interconnection layer 120, a separation pattern 130, color filters CF, a fence pattern 150, and a microlens ML.

The first semiconductor substrate 110 may include a pixel array region APS, an optical black region OB, and a pad region PAD when viewed in plan view. The pixel array region APS may be provided in a center of a first semiconductor substrate 110 when viewed in plan view. The pixel array region APS may include a plurality of pixels PXL.

The pixels PXL may output a photoelectric signal from incident light. The pixels PXL may be two-dimensionally arranged in rows and columns. The rows may be parallel to the first direction D1. The columns may be parallel to the second direction D2. In one or more example embodiments, the first direction D1 may be parallel to a first surface 110a of the first semiconductor substrate 110.

The pad region PAD may be an edge region of the first semiconductor substrate 110. For example, the pad region PAD of the first semiconductor substrate 110 may be provided between the pixel array region APS and a side surface of the first semiconductor substrate 110 when viewed in plan view. The pad region PAD may surround the pixel array region APS when viewed in plan view. Bonding pads 193 may be provided on the pad region PAD. The bonding pads 193 may output electrical signals, generated in the pixels PXL, to an external entity. Alternatively, an external electrical signal or voltage may be transmitted to the pixels PXL through the bonding pads 193. Because the pad region PAD is an edge region of the first semiconductor substrate 110, the bonding pads 193 may be easily connected to an external entity.

Hereinafter, the pixel array region APS of the first chip 100 of the image sensor will be described in more detail.

The first semiconductor substrate 110 may have a first surface 110a and a second surface 110b opposing each other. The first surface 110a of the first semiconductor substrate 110 may be a front surface, and the second surface 110b may be a rear surface. Light may be incident on the second surface 110b of the first semiconductor substrate 110. The first semiconductor substrate 110 may be a semiconductor substrate or a silicon-on-insulator (SOI) substrate. The first semiconductor substrate 110 may include, for example, a silicon substrate, a germanium substrate, or a silicon-germanium substrate. The first semiconductor substrate 110 may further include group III elements. The group III elements may be impurities of a first conductivity type. Accordingly, the first semiconductor substrate 110 may have the first conductivity type. For example, the first conductivity type impurities may include P-type impurities such as aluminum (Al), boron (B), indium (In), and/or gallium (Ga).

A plurality of pixels PXL may be provided on the first semiconductor substrate 110. Photoelectric conversion regions PD corresponding to each pixel PXL may be provided on the first semiconductor substrate 110. The photoelectric conversion regions PD may be interposed between the first surface 110a and the second surface 110b of the first semiconductor substrate 110. The photoelectric conversion regions PD may be doped regions including impurities of a second conductivity type. In one or more example embodiments, the photoelectric conversion regions PD may include group V elements, and the group V elements may be impurities of the second conductivity type. The impurities of the second conductivity type may have a conductivity type opposite to that of the impurities of the first conductivity type. The impurities of the second conductivity type may include N-type impurities such as phosphorus, arsenic, bismuth, and/or antimony. The photoelectric conversion regions PD may be provided in locations spaced apart from the second surface 110b of the first semiconductor substrate 110.

The separation pattern 130 may be provided in the first semiconductor substrate 110, and may define pixels PXL. For example, the separation pattern 130 may be provided between the pixels PXL of the first semiconductor substrate 110. The separation pattern 130 may be provided in a trench, and the trench may be recessed from the first surface 110a of the first semiconductor substrate 110. The separation pattern 130 may be a deep trench isolation layer. The separation pattern 130 may penetrate through the first surface 110a and the second surface 110b of the first semiconductor substrate 110. An upper surface of the separation pattern 130 may be coplanar with the second surface 110b of the first semiconductor substrate 110.

The separation pattern 130 may include a first separation pattern, provided in a trench, and a second separation pattern interposed between the first separation pattern and the first semiconductor substrate 110. The second separation pattern may include a crystalline semiconductor material such as polysilicon. In one or more example embodiments, the first separation pattern may further include a dopant, and the dopant may include impurities of the first conductivity type or impurities of the second conductivity type. For example, the first separation pattern may include doped polysilicon. The second separation pattern may be provided along a sidewall of the trench. The second separation pattern may include, for example, a silicon-based insulating material (for example, a silicon nitride (Si₃N₄), a silicon oxide (SiO₂, silicate), and/or a silicon carbon nitride (SiCN)) and/or a high-κ metal oxide (for example, a hafnium oxide (HfOx), a zirconium oxide (ZrO₂), a titanium oxide (TiO₂), an aluminum oxide (Al₂O₃, alumina), or the like). According to one or more example embodiments, the second separation pattern may include a plurality of layers, and the plurality of layers may include different materials. The second separation pattern may have a lower refractive index than the first semiconductor substrate 110. Accordingly, crosstalk between the pixels PXL may be prevented/reduced. The first separation pattern may be spaced apart from the first semiconductor substrate 110 by the second separation pattern. Accordingly, the first separation pattern may be electrically separated from the second semiconductor substrate 210 during the operation of the image sensor.

The color filters CF may be provided for each pixel PXL on the second surface 110b of the first semiconductor substrate 110. For example, the color filters CF may be provided in locations corresponding to the photoelectric conversion regions PD. Each of the color filters CF may include one of a red filter, a blue filter, and a green filter. However, embodiments are not limited thereto, and filters of other colors may be provided. The color filters CF may constitute color filter arrays. For example, the color filters CF may be arranged in the first direction D1 and the second direction D2 to constitute an array when viewed in plan view.

The fence pattern 150 may be provided on the separation pattern 130. For example, the fence pattern 150 may vertically overlap the separation pattern 130. The fence pattern 150 may have a planar shape corresponding to the separation pattern 130. For example, the fence pattern 150 may have a grid shape when viewed in plan view. The fence pattern 150 may surround the color filters CF when viewed in plan view. The fence pattern 150 may be interposed between two adjacent color filters CF. The plurality of color filters CF may be physically and optically separated from each other by the fence pattern 150. The fence pattern 150 may include a low refractive index material. The low refractive index material may include a polymer and silica nanoparticles in the polymer. The low refractive index material may have insulating properties. According to one or more example embodiments, the fence pattern 150 may include metal and/or metal nitride. For example, the fence pattern 150 may include titanium and/or titanium nitride.

An upper insulating layer 140 may be interposed between the first semiconductor substrate 110 and the color filters CF and between the separation pattern 130 and the fence pattern 150. The upper insulating layer 140 may cover the second surface 110b of the first semiconductor substrate 110 and an upper surface of the separation pattern 130. The upper insulating layer 140 may include an antireflective layer. The upper insulating layer 140 may include a plurality of layers.

The first protective layer 160 may conformally cover an upper surface of the upper insulating layer 140, a sidewall of the fence pattern 150, and an upper surface of the fence pattern 150. For example, a thickness of the upper insulating layer 140 on the sidewall of the fence pattern 150 may be substantially the same as a thickness of the upper insulating layer 140 on the upper surface of the fence pattern 150. The first protective layer 160 may include a high-K dielectric material and may have insulating properties. For example, a first protective layer 160 may include an aluminum oxide or a hafnium oxide. The first protective layer 160 may protect the photoelectric conversion regions PD of the first semiconductor substrate 110 from an external environment.

The microlens ML may be provided on the second surface 110b of the first semiconductor substrate 110. For example, the microlens ML may be provided on the color filters CF and the fence pattern 150. The microlens ML may include a lens pattern and a planarized portion. The planarized portion of the microlens ML may be provided on the color filters CF. The lens pattern may be provided on the planarized portion. The lens pattern may be provided to be integrated with the planarized portion and may be connected to the planarized portion without a boundary. The lens pattern may include the same material as the planarized portion. According to one or more example embodiments, the planarized portion may be omitted and the lens pattern may be directly provided on the color filters CF.

The lens pattern may be hemispherical. The lens pattern may concentrate incident light. The lens pattern may be provided in a location corresponding to the photoelectric conversion regions PD of the first semiconductor substrate 110. For example, the lens pattern may be provided on the photoelectric conversion region PD of the first pixel PXL of the first semiconductor substrate 110.

The microlens ML may be transparent, allowing light to pass therethrough. The microlens ML may include an organic material such as a polymer. For example, the microlens ML may include a photoresist material or a thermosetting resin.

A second protective layer 170 may be provided on the microlens ML to cover the lens pattern. The second protective layer 170 may have a substantially uniform thickness.

The second protective layer 170 may include an organic material and/or an inorganic material. According to one or more example embodiments, the second protective layer 170 may include a silicon-containing material, including, but not limited to, a silicon oxide, a silicon nitride, a silicon oxynitride, a silicon carbide, a silicon carbon oxide, a silicon carbon nitride, and/or a silicon carbon oxynitride. According to one or more example embodiments, the second protective layer 170 may include an aluminum oxide, a zinc oxide, and/or a hafnium oxide. The second protective layer 170 may have insulating properties, but embodiments are not limited thereto. The second protective layer 170 may allow light to pass therethrough.

A first circuit interconnection layer 120 may be provided on the first surface 110a of the first semiconductor substrate 110.

The first circuit interconnection layer 120 may include a first circuit portion 121 including a gate pattern 121a, a gate insulating pattern 121b, an impurity region 121c, and a device isolation pattern 121d.

Impurity regions 121c may be provided in each of the pixels PXL in the first semiconductor substrate 110. The impurity regions 121c may be provided adjacent to the first surface 110a of the first semiconductor substrate 110. The impurity regions 121c may be spaced apart from the photoelectric conversion regions PD. The impurity regions 121c may be doped with impurities of the second conductivity type (for example, N-type impurities). The impurity regions 121c may be active regions. The term “active regions” may refer to regions for the operation of a transistor, and may include a floating diffusion region FD and source/drain regions of the transistor. The transistor may include a transfer transistor, a source follower transistor, a reset transistor, or a select transistor.

The device isolation pattern 121d may be provided in the first semiconductor substrate 110. The device isolation pattern 121d may define active regions. For example, in each pixel region PX, the device isolation pattern 121d may define impurity regions 121c, and the impurity regions 121c may be separated from each other by the device isolation pattern 121d. For example, the device isolation pattern 121d may be provided on one side of one of the impurity regions 121c within the first semiconductor substrate 110. The device isolation pattern 121d may be provided in a second trench, and the second trench may be recessed from the first surface 110a of the first semiconductor substrate 110. The device isolation pattern 121d may be a shallow device isolation layer (STI). For example, a height of the device isolation pattern 121d may be smaller than a height of the separation pattern 130. A portion of the device isolation pattern 121d may be further connected to the sidewall of the separation pattern 130. The device isolation pattern 121d may include, for example, a silicon oxide, a silicon nitride, and/or a silicon oxynitride.

The gate pattern 121a may be provided on the first surface 110a of the first semiconductor substrate 110. The gate pattern 121a may function as a gate electrode of a transfer transistor, a source-follower transistor, a reset transistor, or a select transistor, as described above according to one or more example embodiments. For example, the gate pattern 121a may include a transfer gate, a source-follower gate, a reset gate, or a select gate. In the drawings, a single gate pattern is illustrated as being provided in each pixel PX, but according to one or more example embodiments, a plurality of gate patterns 121a may be provided in each pixel PX. Hereinafter, a single gate pattern 121a will be described for brevity of description.

The gate pattern 121a may have a buried gate structure. For example, the gate pattern 121a may include a first portion and a second portion. The first portion of the gate pattern 121a may be provided on the first surface 110a of the first semiconductor substrate 110. The second portion of the gate pattern 121a may protrude inwardly relative to the first semiconductor substrate 110. The second portion of the gate pattern 121a may be provided on an upper surface of the first portion to be connected to the first portion. Unlike what is illustrated in FIG. 4B, the gate pattern 121a may have a planar gate structure. In this case, the gate pattern 121a may not include the second portion. The gate pattern 121a may include a metal material, a metal silicide material, polysilicon, or combinations thereof. In this case, the polysilicon may include doped polysilicon.

A gate insulating pattern 121b may be interposed between the gate pattern 121a and the first semiconductor substrate 110. The gate insulating pattern 121b may include, for example, a silicon-based insulating material (for example, a silicon oxide, a silicon nitride, and/or a silicon oxynitride) and/or a high-K dielectric material (for example, a hafnium oxide and/or an aluminum oxide).

The first circuit interconnection layer 120 may include a first lower insulating layer 123 and a first conductive structure 125. The first lower insulating layer 123 may cover the first surface 110a of the first semiconductor substrate 110 and may be provided as a multilayer structure. The first lower insulating layers 123 may include, for example, a silicon-based insulating material such as a silicon oxide, a silicon nitride, and/or a silicon oxynitride.

The first conductive structure 125 may be provided in the stacked first lower insulating layer 123. The first conductive structure 125 may include an interconnection portion and a via portion. The interconnection portion may be provided in the first lower insulating layer 123 and may be electrically connected to one of the impurity regions 121c and the gate pattern 121a. Also, the interconnection portion may be interposed between two adjacent lower insulating layers. A via portion of the first conductive structure 125 may penetrate through at least one of the first lower insulating layers 123, and may be connected to the interconnection portion. The first conductive structure 125 may receive photoelectric signals output from the photoelectric conversion regions PD.

Hereinafter, the optical black region OB and the pad region PD will be described according to one or more example embodiments.

The optical black region OB of the first semiconductor substrate 110 may be interposed between the pixel array region APS and the pad region PD. Similar to the pixel array region APS, the optical black region OB may include a portion, in which the photoelectric conversion region PD is provided, and a portion in which the photoelectric conversion region PD is not provided. The impurity region 121c, the gate pattern 121a, and the device isolation pattern 121d may be provided in each pixel PXL in the optical black region. The impurity region 121c, the gate pattern 121a, and the device isolation pattern 121d may be the same as those described above.

The upper insulating layer 140 may extend upward relative to the optical black region OB and the pad region PD of the first semiconductor substrate 110, and may cover the second surface 110b of the first semiconductor substrate 110.

A light shielding layer 187 and an organic insulating layer 181 may be provided in the optical black region OB. The light shielding layer 187 may be provided on the upper insulating layer 140. The light shielding layer 187 may prevent light from being incident to the photoelectric conversion region PD of the optical black region OB. Pixels PXL of the optical black region OB may output a noise signal, rather than a photoelectric signal. The noise signal may be generated from electrons produced by heat generation or dark current. According to one or more example embodiments, the light shielding layer 187 may not cover the pixel array region APS, allowing light to be incident to the photoelectric conversion regions PD within the pixel array region APS. The light shielding layer 187 may include, for example, metal such as tungsten, copper, aluminum, or alloys thereof.

The organic insulating layer 181 may be provided on the light shielding layer 187. The organic insulating layer 181 may be transparent. An upper surface of the organic insulating layer 181 may be substantially planar with an upper surface of the first semiconductor substrate 110. The organic insulating layer 181 may include, for example, a polymeric organic material and may have insulating properties. In one or more example embodiments, the organic insulating layer 181 may include the same material as the fence patterns 150. According to one or more example embodiments, the organic insulating layer 181 may include the same material as the microlens ML. In this case, the organic insulating layer 181 may be connected to the microlens ML, but embodiments are not limited thereto.

The image sensor may further include at least one of a contact plug 195, a first conductive pattern 191a, a protective insulating layer 183, and a filtering layer 185. The first conductive pattern 191a may be provided on the optical black region OB and the pad region PD of the second surface 110b of the first semiconductor substrate 110. The first conductive pattern 191a may be provided between the upper insulating layer 140 and the light shielding layer 187. The first conductive pattern 191a may be configured as a barrier layer or an adhesive layer. The first conductive pattern 191a may include metal and/or metal nitride. For example, the first conductive pattern 191a may include titanium and/or titanium nitride. According to one or more example embodiments, the first conductive pattern 191a may not extend upwardly relative to the pixel array region APS of the first semiconductor substrate 110.

A contact plug 195 may be provided on an upper surface of an outermost portion of the separation pattern 130. The contact plug 195 may be provided in a trench 195h provided on the second surface 110b of the first semiconductor substrate 110. The contact plug 195 may include a material, different from a material of the light shielding layer 187. For example, the contact plug 195 may include a metal material such as aluminum. The first conductive pattern 191a may extend between the contact plug 195 and the insulating layer and between the contact plug 195 and the separation pattern 130. The contact plug 195 may be electrically connected to the separation pattern 130 through the first conductive pattern 191a. Accordingly, a negative bias voltage may be applied to the separation pattern 130 through the contact plug 195.

A filtering layer 185 may be interposed between the light shielding layer 187 and the organic insulating layer 181. The filtering layer 185 may block light having a wavelength, different from a wavelength of light produced from the color filters CF. For example, the filtering layer 185 may block an infrared ray. The filtering layer 185 may include a blue color filter, but embodiments are not limited thereto.

The protective insulating layer 183 may be interposed between the light shielding layer 187 and the filtering layer 185. The protective insulating layer 183 may cover an upper surface of the light shielding layer 187 and an upper surface of the contact plug 195. The protective insulating layer 183 may include the same material as the first protective layer 160, and may be connected to the first protective layer 160. The protective insulating layer 183 may be integrated with the first protective layer 160. According to one or more example embodiments, the protective insulating layer 183 may be formed by a process, separate from a process of forming the first protective layer 160, and may be spaced apart from the first protective layer 160. The protective insulating layer 183 may include a high-K dielectric material (for example, an aluminum oxide and/or a hafnium oxide).

The first circuit interconnection layer 120 may be provided on the first surface 110a of the first semiconductor substrate 110, and may extend to the optical black region OB and the pad region PAD of the first semiconductor substrate 110.

The second chip 200 may be provided below the above-described first chip 100 with the bonding portion 300 interposed between the first chip 100 and the second chip 200.

A logic circuit may be mounted on the second chip 200. The second chip 200 may include a second circuit interconnection layer 220 and a second semiconductor substrate 210.

The second semiconductor substrate 210 may have a third surface 210a and a fourth surface 210b opposing each other. The third surface 210a of the second semiconductor substrate 210 may oppose the first surface 110a of the first semiconductor substrate 110, and the fourth surface 210b of the second semiconductor substrate 210 may oppose the third surface 210a of the first semiconductor substrate 110.

The second circuit interconnection layer 220 may be provided on the fourth surface 210b. For example, the second circuit interconnection layer 220 may be interposed between the first circuit interconnection layer 120 and the second semiconductor substrate 210, and may include a second circuit portion 220, a second lower insulating layer 223, and a second conductive structure 225.

The second circuit unit 220 may include integrated circuits, and may be provided on an upper surface of the second semiconductor substrate 210 or may be provided within the second semiconductor substrate 210. The integrated circuits may include logic circuits, memory circuits, or combinations thereof. The integrated circuits may include, for example, transistors.

Each of the second conductive structures 225 may include an interconnection pattern and a via pattern. The interconnection pattern may be provided between the second lower insulating layers 223. The via pattern may be provided in the second lower insulating layers 223. The second conductive structures 225 may be electrically connected to the integrated circuits. The second conductive structures 225 may include metal.

The pad region PAD may be provided with a connection portion for connection to an external entity and may electrically connect to the first chip 100 and/or the second chip 200. To this end, the connection portion may be provided with a bonding pad 193 and first and second through-holes.

The bonding pad 193 may be provided on the pad region PAD of the first surface 110a of the first semiconductor substrate 110. The bonding pad 193 may be buried in the first semiconductor substrate 110. For example, a pad trench may be provided on the pad region PAD of the first surface 110a of the first semiconductor substrate 110, and the bonding pad 193 may be provided in the pad trench. The bonding pad 193 may include metal such as aluminum, copper, tungsten, titanium, tantalum, or alloys thereof. In a mounting process of the image sensor, a bonding wire may be provided on the bonding pads 193 to be connected to the bonding pad 193. The bonding pad 193 may be electrically connected to an external device through the bonding wire.

The first through-hole 197 may be provided on one side of the bonding pad 193. The first through-hole 197 may be provided between the bonding pad 193 and the contact plug 195. The first through-hole 197 may penetrate through the upper insulating layer 140, the first semiconductor substrate 110, and the first circuit interconnection layer 120. The first through-hole 197 may further penetrate through at least a portion of the second circuit interconnection layer 220. The first through-hole 197 may have a first bottom surface and a second bottom surface. The first bottom surface of the first through-hole 197 may expose the first conductive structure 125. The second bottom surface of the first through-hole 197 may be provided at a lower level than the first bottom surface. The second bottom surface of the first through-hole 197 may expose the second conductive structure 225.

The first conductive pattern 191a may overlap the pad region PAD of the first semiconductor substrate 110 and may be provided on the upper insulating layer 140. The first conductive pattern 191a may cover an internal sidewall of the first through-hole 197. A plurality of bonding pads 193 may be provided.

The plurality of bonding pads 193 may include a first one of the bonding pads 193 and a second one of the bonding pads 193. The first conductive pattern 191a may be provided on a lower surface and a sidewall of a single bonding pad (for example, the first one of the bonding pads 193), from among the plurality of bonding pads 193, and may be electrically connected to the single bonding pad (for example, the first one of the bonding pads 193). The first conductive pattern 191a may cover the sidewall and the first bottom surface of the first through-hole 197. The first conductive pattern 191a may be in contact with the upper surface of the first conductive structure 125. Accordingly, the first conductive structure 125 may be electrically connected to the single bonding pad 193 (for example, the first one of the bonding pads 193) through the first conductive pattern 191a. When the image sensor operates, a voltage may be applied to the first conductive structure 125 through the single bonding pad 193 and the first conductive pattern 191a. The voltage may be applied to the second separation pattern 130 through the first conductive pattern 191a and the contact plug 195. The voltage may be a negative bias voltage.

The first conductive pattern 191a may cover the second bottom surface of the first through-hole 197 and may be connected to an upper surface of the second conductive structure 225. Integrated circuits in the second chip 200 may be electrically connected to the single bonding pad 193 through the second conductive structure 225 and the first conductive pattern 191a. A plurality of first conductive patterns 191a and a plurality of first through-holes 197 may be provided. According to one or more example embodiments, among the plurality of first conductive patterns 191a, a single first one of the conductive patterns 191a may not be connected to the contact plug 195 and may be connected to the first conductive structure 125 or the second conductive structure 225. The single first one of the conductive pattern 191a may function as an electrical path between the integrated circuits of the second chip 200 and the transistor of the first chip 100. The first conductive patterns 191a may include metal such as copper, tungsten, aluminum, titanium, tantalum, or alloys thereof. Hereinafter, a singular one of the first conductive patterns 191a will be described.

The image sensor may further include at least one of a first buried pattern 197a and a first capping pattern 197b. The first buried pattern 197a and the first capping pattern 197b may be provided on the pad region PAD of the first semiconductor substrate 110. The first buried pattern 197a may be provided in the first through-hole 197 to cover the first conductive pattern 191a. The first buried pattern 197a may fill at least a portion of the first through-hole 197. The first buried pattern 197a may not extend upward relative to the second surface 110b of the first semiconductor substrate 110. The first buried pattern 197a may include a low refractive index material and may have insulating properties. The first buried pattern 197a may include the same material as the fence pattern 150. For example, the first buried pattern 197a may include a polymer and silica nanoparticles. An upper surface of the first buried pattern 197a may be concave. For example, a central portion of the upper surface of the first buried pattern 197a may be provided at a lower level than an edge portion of the upper surface of the first buried pattern 197a.

The first capping pattern 197b may be provided on an upper surface of the first buried pattern 197a. An upper surface of the first capping pattern 197b may be substantially planar. The upper surface of the first capping pattern 197b may be covered with the filtering layer 185. The first capping pattern 197b may include an insulating polymer such as a photoresist material.

The second through-hole 199 may be provided on the other side of the bonding pad 193. The second through-hole 199 may penetrate through the insulating layer, the first semiconductor substrate 110, and the first circuit interconnection layer 120. The second through-hole 199 may further penetrate through a portion of the second circuit interconnection layer 220 to expose the second conductive structure 225.

The image sensor may further include a second conductive pattern 191b, a second buried pattern 199a, and a second capping pattern 199b. The second conductive pattern 191b may be provided on the second surface 110b of the first semiconductor substrate 110. As illustrated, the second conductive pattern 191b may be interposed between another single bonding pad (for example, the second one of the bonding pads 193), from among the bonding pads 193, and the first semiconductor substrate 110, and may be electrically connected to the single bonding pad 193. The second conductive pattern 191b may extend inwardly of the second through-hole 199 to conformally cover a sidewall and a bottom surface of the second through-hole 199. The second conductive pattern 191b may be electrically connected to the second conductive structure 225. During the operation of the image sensor, the integrated circuits of the second chip 200 may transmit and receive electrical signals through the second conductive structure 225, the second conductive pattern 191b, and the single bonding pad 193 (for example, the second one of the bonding pads 193).

A second buried pattern 199a may be provided in the second through-hole 199 and may fill the second through-hole 199. The second buried pattern 199a may not extend upward relative to the second surface 110b of the first semiconductor substrate 110. The second buried pattern 199a may include a low refractive index material, and may have insulating properties. For example, the second buried pattern 199a may include the same material as at least one of the fence pattern 150 and the first buried pattern 197a. An upper surface of the second buried pattern 199a may be concave.

A second capping pattern 199b may be provided on an upper surface of the second buried pattern 199a. An upper surface of the second capping pattern 199b may be substantially planar. The second capping pattern 199b may include an insulating polymer such as a photoresist material.

The protective insulating layer 183 may extend upwardly of the pad region PAD of the first semiconductor substrate 110, and may cover the first conductive pattern 191a and the second conductive pattern 191b. The protective insulating layer 183 may extend inwardly of the first through-hole 197 and the second through-hole 199. The protective insulating layer 183 may be interposed between the first conductive pattern 191a and the first buried pattern 197a within the first through-hole 197. The protective insulating layer 183 may be interposed between the second conductive pattern 191b and the second buried pattern 199a within the second through-hole 199. The protective insulating layer 183 may expose the bonding pad 193.

The organic insulating layer 181 may be further provided on the pad region PAD of the first semiconductor substrate 110. The organic insulating layer 181 may cover a portion of the protective insulating layer 183, the first capping pattern 197b, and the second capping pattern 199b. The organic insulating layer 181 may expose an upper surface of the bonding pad 193.

The second passivation layer 170 may extend upwardly of the optical black region OB and the pad region PAD of the first semiconductor substrate 110 to cover the organic insulating layer 181.

The bonding portion 300 may be provided between the first chip 100 and the second chip 200 to connect the first chip 100 and the second chip 200 to each other.

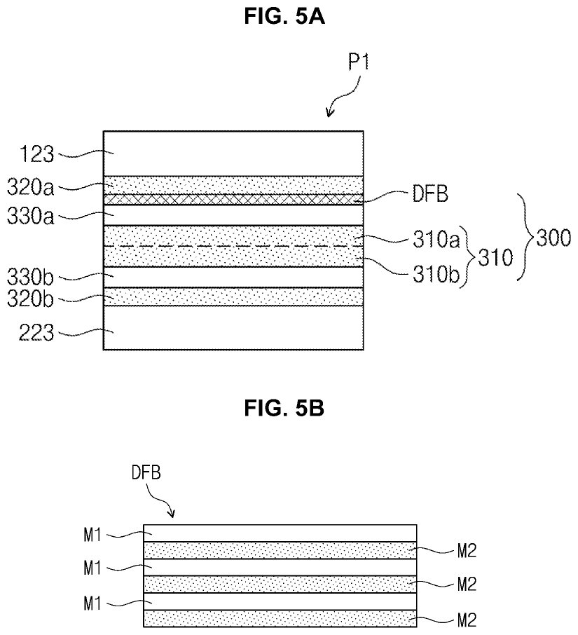

FIG. 5A is a diagram illustrating the bonding portion 300 in FIG. 4B in detail and is an enlarged cross-sectional view of portion P1 of FIG. 4B, and FIG. 5B is an enlarged view of the diffusion barrier layer of FIG. 5A according to one or more example embodiments.

Referring to FIG. 5A, the bonding portion 300 may be provided between the first circuit interconnection layer 120 of the first chip 100 and the second circuit interconnection layer 220 of the second chip 200. The bonding portion 300 may include a bonding layer 310, connecting the first chip 100 to the second chip 200, and a diffusion barrier layer DFB provided between the circuit interconnection layer 120 and the bonding layer 310 to prevent diffusion of hydrogen and/or deuterium.

In one or more example embodiments, the bonding layer 310 may include a material, capable of being bonded through a process such as an annealing process and/or a plasma treatment. The bonding layer 310 may include a first bonding layer 310a, provided on the first chip 100, and a second bonding layer 310b provided on the second chip 200. The first and second bonding layers 310a and 310b may be integrally bonded without being separated from each other, through the annealing process and/or the plasma treatment. As a result, the bonding of the first chip 100 and the second chip 200 may be completed.

The first and second bonding layers 310a and 310b may be, for example, an insulating material bonded by the annealing process and/or the plasma treatment. Examples of such an insulating material may include a silicon carbon nitride, a silicon oxide (for example, silicate), or a silicon nitride.

The first and second bonding layers 310a and 310b may include a metal material. For example, the first and second bonding layers 310a and 310b may be formed of a bonding metal. In this case, the bonding layer 310 may have a bonding structure formed by copper-copper (Cu—Cu) bonding.

In one or more example embodiments, the first bonding layer 310a may include SiCN.

The diffusion barrier layer DFB may be provided between a first driving element and a bonding layer 310 to prevent hydrogen (H₂) and/or deuterium (D₂) from diffusing from the first chip 100 to the second chip 200. A process of fabricating the image sensor according to one or more example embodiments may include a process of treating the semiconductor substrate 110 with hydrogen and/or deuterium, and the image sensor may be provided between the first chip 100 and the second chip 200, for example, the first circuit interconnection layer 120 and the second circuit interconnection layer 220, to prevent hydrogen and/or deuterium from reaching the second circuit interconnection layer 220 of the second semiconductor substrate 210 during the fabricating process.

The diffusion barrier layer DFB may include a material having a diffusion coefficient, lower than a diffusion coefficient of hydrogen and/or deuterium, to prevent diffusion of hydrogen and/or deuterium. For example, the diffusion barrier layer DFB may have a diffusion coefficient of 1.0×10⁻¹⁴ cm²/s or less.

To this end, the diffusion barrier layer DFB may include, for example, an aluminum oxide (Al₂O₃, for example, alumina), a silicon carbon nitride (SiCN), a silicon nitride (Si₃N₄), a zirconium oxide (ZrO₂), a titanium oxide (TiO₂), a titanium oxide, a silicon oxide (SiO₂, for example, silicate), a hafnium oxide, or the like. In one or more example embodiments, the diffusion barrier layer DFB may be an aluminum oxide or alumina (Al₂O₃) layer or a silicon nitride (Si₃N₄) layer.

In one or more example embodiments, the diffusion barrier layer DFB may be provided as a single-layer structure or a multilayer structure. When the diffusion barrier layer DFB is provided as a single-layer structure, the diffusion barrier layer DFB may be an aluminum oxide (for example, alumina) layer, a silicon carbon nitride layer, a silicon nitride layer, a zirconium oxide layer, a titanium oxide layer, a silicon oxide (for example, silicate) layer, a hafnium oxide layer, or the like. When the diffusion barrier layer DFB is provided as a multilayer structure, the diffusion barrier layer DFB may include a layer formed of at least two or more types of materials.

In one or more example embodiments, the diffusion barrier layer DFB may include a first layer M1 and a second layer M2, respectively formed of two types of materials, for example, a first material and a second material, as illustrated in FIG. 5B. According to one or more example embodiments, a plurality of first layers M1 and a plurality of second layers M2 may be provided. According to one or more example embodiments, a plurality of first layers M1 and a plurality of second layers M2 may be alternately provided. FIG. 5B illustrates an example in which a diffusion barrier layer DFB includes a first layer M1 and a second layer M2, and the first layer M1 and the second layer M2 may be alternately provided.

However, the configuration of the diffusion barrier layer DFB is not limited thereto, and the diffusion barrier layer DFB may be configured to have a layer formed of three or more different types of materials. The material of the first layer M1 and the material of the second layer M2 are not limited as long as the materials are capable of preventing diffusion of hydrogen and/or deuterium, and may include combinations of various materials. For example, the diffusion barrier layer DFB may include a single layer formed of a single material, a single layer formed by mixing two or more materials, multiple layers formed of different materials, a composite layer formed by stacking different multiple layers formed of different materials, or any combination thereof.

For example, the diffusion barrier layer DFB may include combinations of a single layer of Al₂O₃, a single layer of Si₃N₄, a multilayer structure of (SiCN/Al₂O₃/SiCN/Al₂O₃/to SiCN/Al₂O₃) and (SiCN/Al₂O₃/oxide/Al₂O₃/to oxide/Al₂O₃), a multilayer structure of (SiCN/Si₃N₄/SiCN/Si₃N₄/to SiCN/Si₃N₄) and (SiCN/Si₃N₄/Oxide/Si₃N₄/to oxide/Si₃N₄), and a composite layer or a multilayer structure of (SiCN/Al₂O₃/Si₃N₄) and (SiCN/Al₂O₃/oxide/Si₃N₄/to oxide/Si₃N₄).

In one or more example embodiments, the diffusion barrier layer DFB may have a thickness of about 10 angstroms to about 10,000 angstroms. When the diffusion barrier layer DFB has a thickness less than about 10 angstroms, it may be difficult to prevent hydrogen and/or deuterium from permeating. When the diffusion barrier layer DFB has a thickness of about 10,000 angstroms or more, stress may occur depending on a thickness of the diffusion barrier layer DFB during bonding of the first and second chips 100 and 200. In one or more example embodiments, the diffusion barrier layer DFB may be set to vary depending on the type of material forming the diffusion barrier layer DFB, the structures and process steps of the first and second chips 100 and 200, or the like. For example, according to one or more example embodiments, the diffusion barrier layer DFB may have a thickness of about 10 angstroms to about 1,000 angstroms, a thickness of about 20 angstroms to about 500 angstroms, or a thickness of about 50 angstroms and about 100 angstroms.

In one or more example embodiments, a first passivation layer 320a may be provided on the first circuit interconnection layer 210 to protect the first circuit interconnection layer 210. In addition, a second passivation layer 320b may be provided on the second circuit interconnection layer 220 to protect the second circuit interconnection layer 220.

The first passivation layer 320a and/or the second passivation layer 320b may be formed of various insulating materials such as a silicon oxide, a silicon oxynitride, or a silicon nitride.

A planarization layer may be provided between first passivation layer 320a and/or the second passivation layer 320b and the bonding layer 310. For example, a first planarization layer 330a may be provided between the first passivation layer 320a and the bonding layer 310, and a second planarization layer 330b may be provided between the second passivation layer 320b and the bonding layer 310. The first and second planarization layers 330a and 330b may be provided to prevent the first semiconductor substrate 110 and second semiconductor substrate 210 from warping during a process of fabricating the image sensor, and may be formed to a predetermined thickness or more.

In one or more example embodiments, the first passivation layer 320a and/or the second passivation layer 320b may include a silicon carbon nitride (SiCN), and the first planarization layer 330a and/or the second planarization layers 330b may include a silicon oxide, for example, plasma enhanced-tetraethyl orthosilicate (PE-TEOS). In addition, the bonding layer 310 may include the same material as the first passivation layer 320a and/or the second passivation layer 320b, for example, a silicon carbon nitride.

Accordingly, in one or more example embodiments, the first passivation layer 320a, the diffusion barrier layer DFB, the first planarization layer 330a, the bonding layer 310, the second planarization layer 330b, and the second passivation layer 320b may be provided in a third direction D3 from the first circuit interconnection layer 120 to the second circuit interconnection layer 220. However, the configuration of the bonding portion 300 is not limited thereto, and various modifications may be made within the scope of one or more example embodiments.

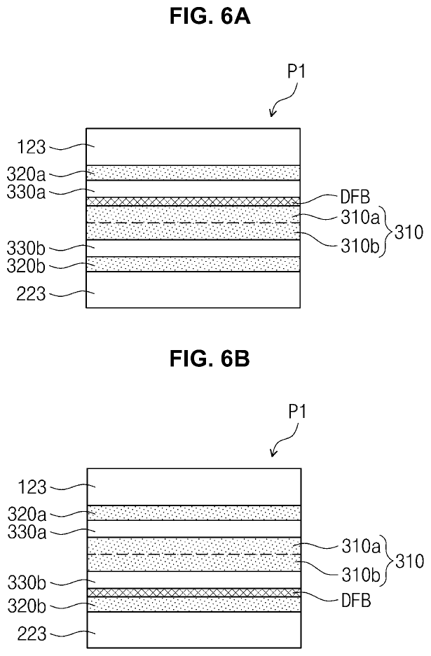

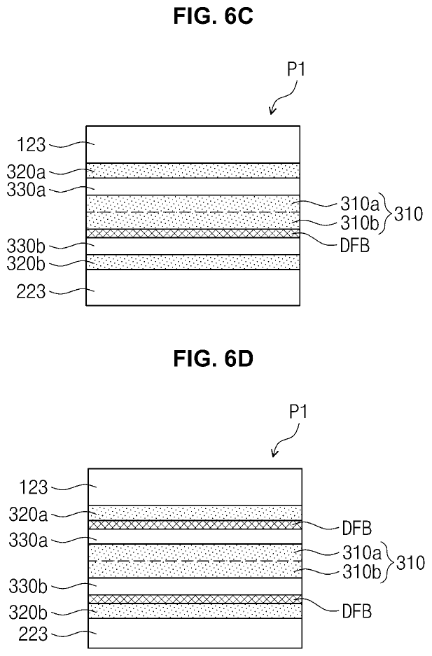

FIGS. 6A, 6B, 6C and 6D are cross-sectional views illustrating a diffusion barrier layer DFB according to one or more example embodiments.

Referring to FIGS. 6A, 6B, 6C and 6D, the diffusion barrier layer DFB may be provided in various numbers and various locations. For example, according to FIG. 6A, the diffusion barrier layer DFB may be provided between a first planarization layer 330a and a first bonding layer 310a, rather than between a first passivation layer 320a and the first planarization layer 330a.

According to FIGS. 6B and 6C, the diffusion barrier layer DFB may be provided on a side of a second chip 200, rather than a side of a first chip 100. For example, the diffusion barrier layer DFB may be provided between a second passivation layer 320b and a second planarization layer 330b on the side of the second chip 200, as illustrated in FIG. 6B. Alternatively, the diffusion barrier layer DFB may be provided between a second planarization layer 330b of the second chip 200 and the bonding layer 310, as illustrated in FIG. 6C.

Also, according to one or more example embodiments, a plurality of diffusion barrier layers DFB may be provided, as illustrated in FIG. 6D. Referring to one or more example embodiments shown in FIG. 6D, a diffusion barrier layer DFB may be provided not only on a side of a first chip 100 but also on a side of a second chip 200, so that they may be provided between a first passivation layer 320a and a first planarization layer 330a and between a second passivation layer 320b and a second planarization layer 330b, respectively. Although two diffusion barrier layers DFB are illustrated in the present embodiment, embodiments are not limited thereto, and three or more diffusion barrier layers may be provided between other layers.

A material of the bonding portion 300 according to an example embodiment may comprise various materials.

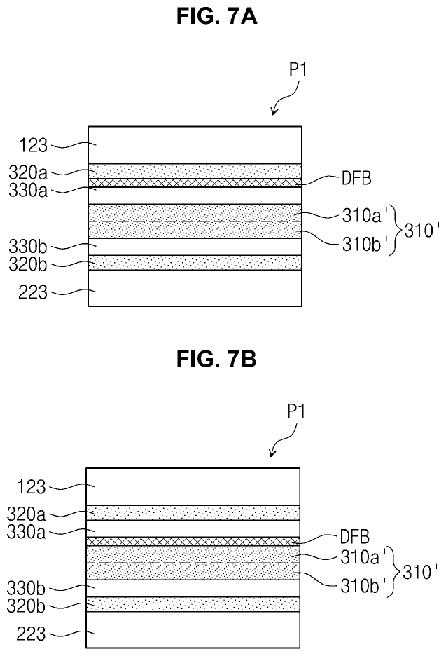

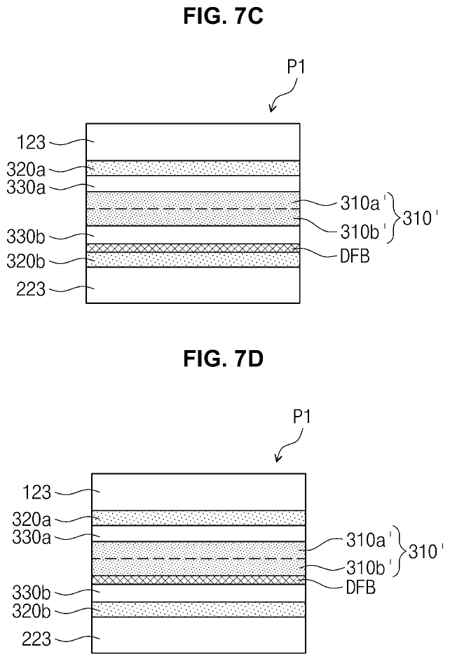

FIGS. 7A, 7B, 7C and 7D are cross-sectional views of a diffusion barrier layer DFB according to one or more example embodiments, and illustrate that a material different from a material of a passivation layer may be used for a bonding layer 310, unlike the above-described one or more example embodiments.

Referring to FIGS. 7A, 7B, 7C and 7D, according to one or more example embodiments, first and second passivation layers 320a and 320b and first and second bonding layers 310a and 310b′ may be formed of different materials. For example, the first and second passivation layers 320a and 320b may be formed of a silicon carbon nitride, and the first and second bonding layers 310a′ and 310b′ may be formed of a silicon oxide. In this case, the diffusion barrier layer DFB may be provided between a first passivation layer 320a and a first planarization layer 330a as illustrated in FIG. 7A, or may be provided between a first planarization layer 330a and a first bonding layer 310a′ as illustrated in FIG. 7B, or may be provided between a second bonding layer 310b′ and a second planarization layer 330b as illustrated in FIG. 7C, or may be provided between a second planarization layer 330b and a second passivation layer 320b as illustrated in FIG. 7D.

According to one or more example embodiments, each of the first polarization layer 330a and/or the second planarization layer 330b and the first bonding layer 310a′ and/or the second bonding layer 310b′ may include a single layer.

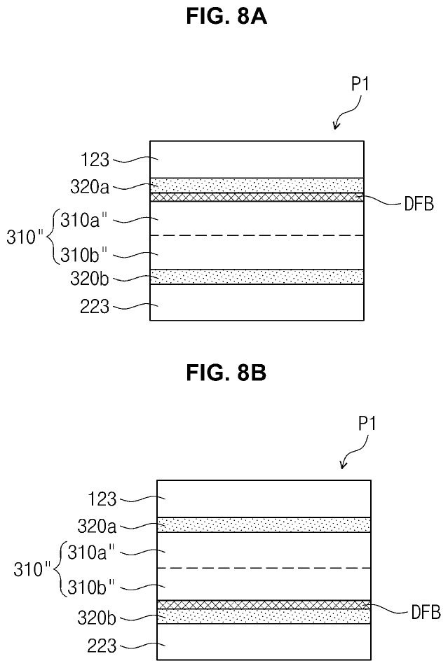

FIGS. 8A and 8B are cross-sectional views of a diffusion barrier layer DFB according to one or more example embodiments, and illustrate that the first planarization layer 330a and the first bonding layer 310a described above may be provided as a single first bonding layer 310a″, and the second planarization layer 330b and the second bonding layer 310b described above may be provided as a single second bonding layer 310b″. This corresponds to an example embodiment in which the first and second planarization layers 330a and 330b are used as the first and second bonding layers 310a″ and 310b″ without formation of an additional layer of a different material. The first and second passivation layers 320a and 320b may include a silicon carbon nitride, and the first and second bonding layers 310a″ and 310b″ may include a silicon oxide, for example, PE-TEOS.

Referring to FIGS. 8A and 8B, the diffusion barrier layer DFB may be provided between the first passivation layer 320a and the first bonding layer 310a″, as shown in FIG. 8A. Alternatively, as shown in FIG. 8B, the diffusion barrier layers DFB may be provided between the second passivation layer 320b and the second bonding layer 310b″.

According to one or more example embodiments, the bonding portion 300 may further include a reflective layer to increase efficiency of light, other than the diffusion barrier layer DFB.

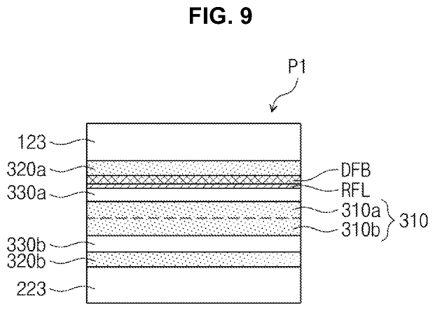

FIG. 9 is a cross-sectional view of a diffusion barrier layer DFB according to one or more example embodiments, and illustrates that a reflective layer RFL is further provided between the diffusion barrier layer DFB and the first planarization layer 330a.

The reflective layer RFL may include a material having reflectivity such that light, entering a photoelectric conversion region PD from the outside, re-enters the photoelectric conversion region PD as much as possible without leaking to the outside. For example, the reflective layer RFL may be formed of a metal material having high reflectivity. Examples of the metal material may include Al, Au, Ag, Ti, Ni, Co, Si, Cu, or alloys thereof.

As shown in FIG. 9, the reflective layer RFL is illustrated as being provided between the diffusion barrier layer DFB and the first planarization layer 330a, but embodiments are not limited thereto. For example, the reflective layer RFL may be provided in various locations such as between the first planarization layer 330a and the first bonding layer 310a, or between the second bonding layer 310b and the second planarization layer 330b.

An image sensor having the above-described structure according to one or more example embodiments may have a stack structure, and may include a diffusion barrier layer DFB, which may prevent hydrogen and/or deuterium from diffusing from the first chip 100 to the second chip 200, to prevent deterioration of elements in the second chip 200.

In a process of manufacturing an image sensor, an interfacial passivation treatment may be performed to improve performance of a chip on which the next photodiode sensor has been provided. For example, an interfacial passivation process may be performed to improve performance of a chip on which a photodiode has been provided. Such a process may be performed to improve characteristics of noise in a sensor chip (for example, a random noise defect or a dark level leakage defect) after formation of a photodiode, and is mainly related to addressing a dangling bond within an interface in a first chip. An interfacial passivation process may be generally performed after an interconnection process of a circuit portion in a sensor chip is performed, and may be mainly performed at a relatively low temperature of about 450 degrees Celsius by high-pressure deuterium annealing (about 20 atmospheric pressure), atmospheric deuterium annealing (about 1 atmospheric pressure), or hydrogen annealing.

However, when an image sensor is fabricated using a stack structure, for example, when an image sensor is fabricated by stacking two or more chips, hydrogen or deuterium may be diffused to reach a lower logic chip during a process of performing an interfacial passivation treatment with such hydrogen or deuterium, resulting in deterioration of elements of a logic chip. Due to such diffusion of hydrogen and/or deuterium, a logic circuit of the second chip may be deteriorated to significantly reduce yield (a defect rate of about 60%). When a hydrogen and/or deuterium treatment is omitted to prevent deterioration of the logic circuit, other defects may occur, so that it may be difficult to omit the hydrogen or deuterium treatment.

In one or more example embodiments, in a structure in which a sensor chip and a logic chip are stacked, a diffusion barrier which may prevent diffusion of hydrogen and/or deuterium may be provided in a bonding portion between a sensor chip (the above-described first chip) and a logic chip (the above-described second chip) to prevent hydrogen and/or deuterium from diffusing to elements of the logic chip. Accordingly, characteristics in a sensor chip, in which a photoelectric conversion sensor is provided, may be improved without deterioration of characteristics of elements in a logic circuit of the second chip.

The image sensor having the above-described structure according to one or more example embodiments may be fabricated by forming a first chip including a first semiconductor substrate and some elements of a pixel, forming a second chip to control the first chip, forming a diffusion barrier layer on an upper surface of at least one of the first chip and the second chip, bonding the first chip and the second chip with the diffusion barrier layer interposed therebetween, planarizing an external side surface of the first chip, performing a hydrogen and/or deuterium treatment on the first chip in a direction from the first chip to the second chip, and forming the other elements of the pixel on the external side surface of the first chip.

This will be described in more detail with reference to one or more example embodiments and the accompanying drawings.

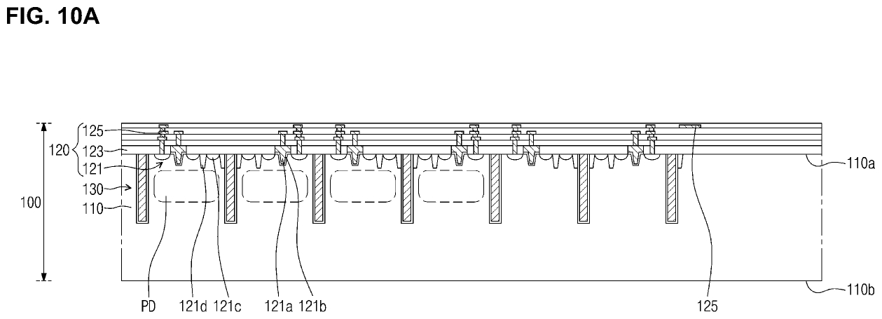

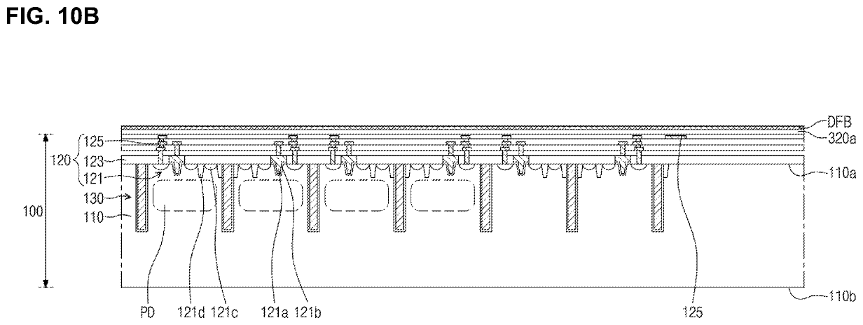

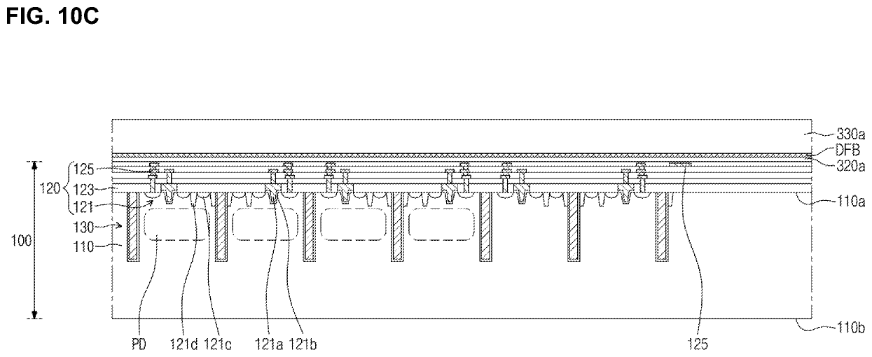

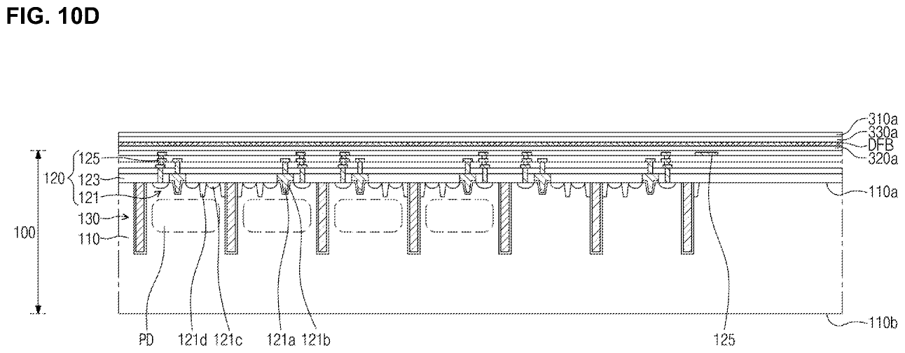

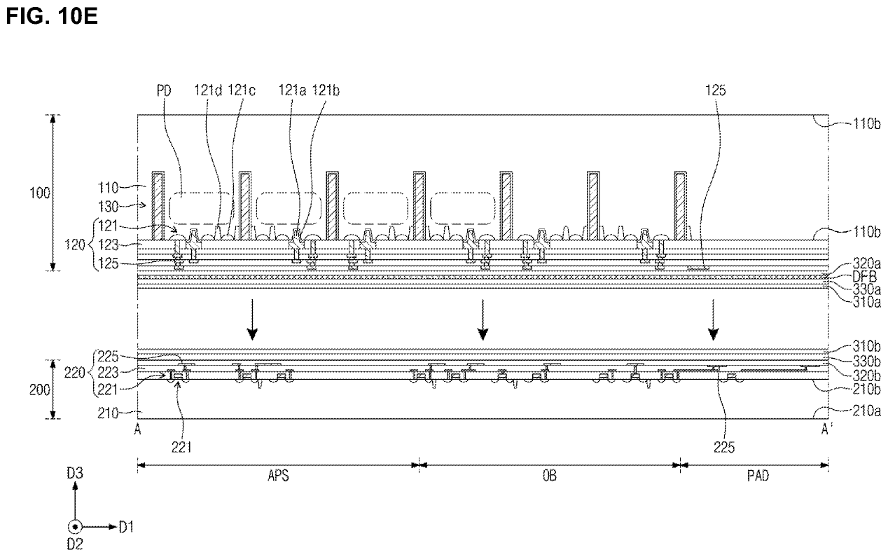

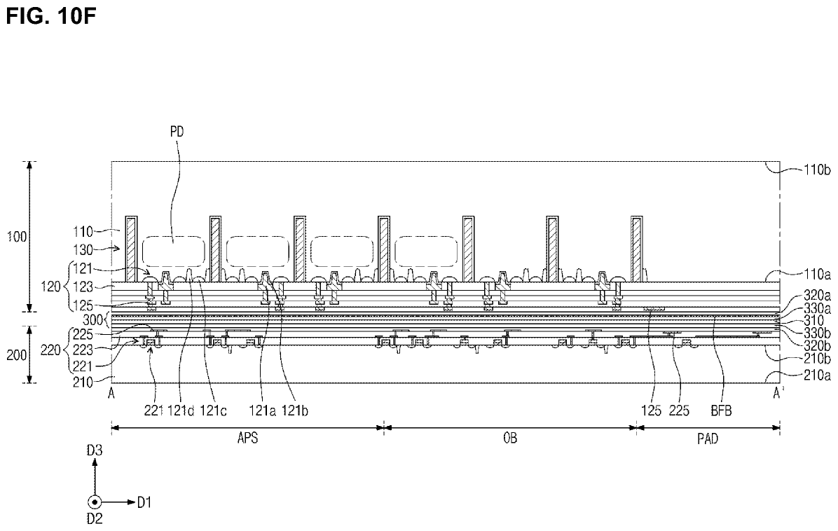

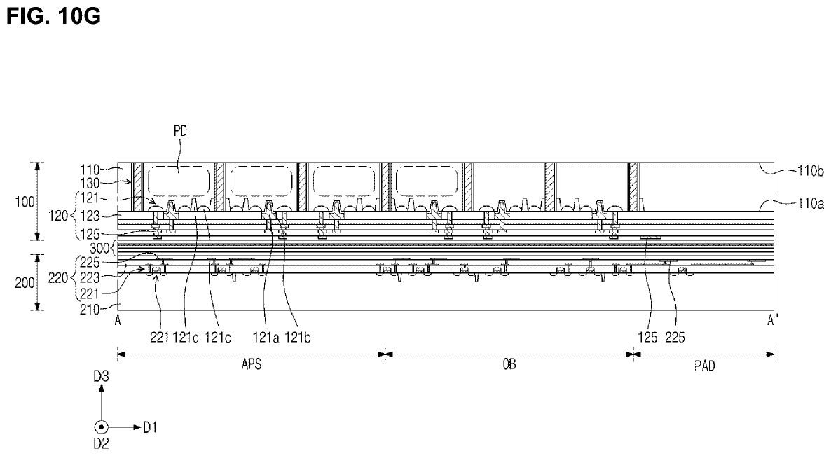

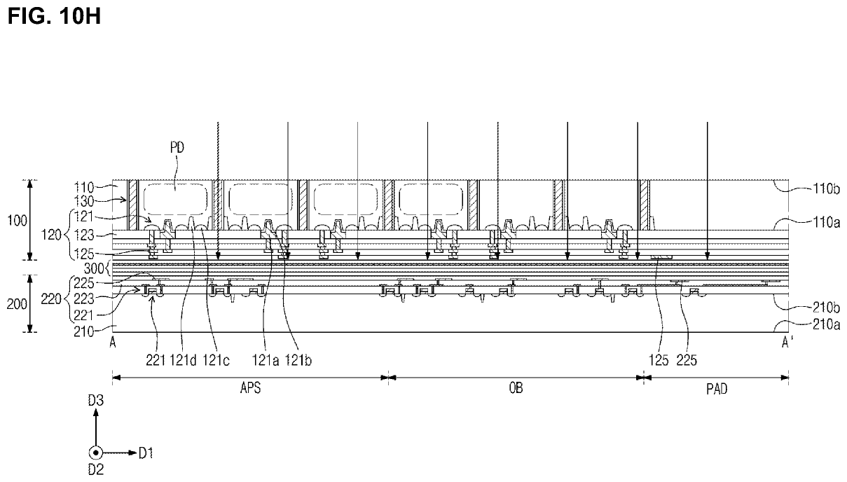

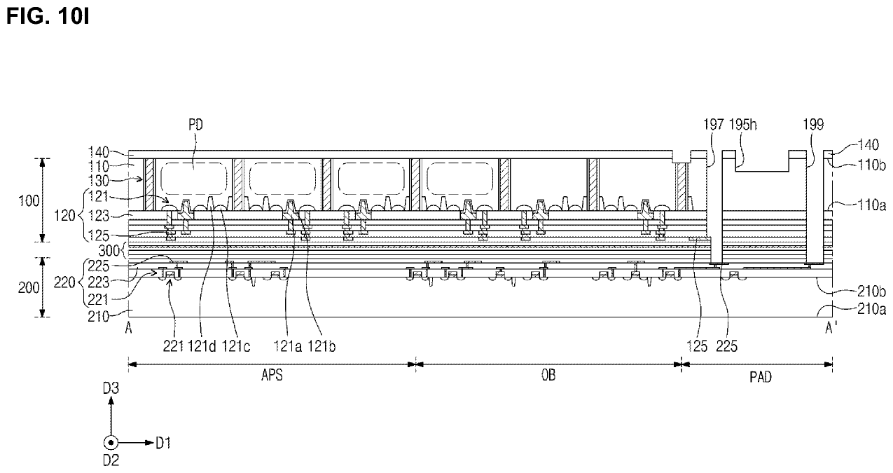

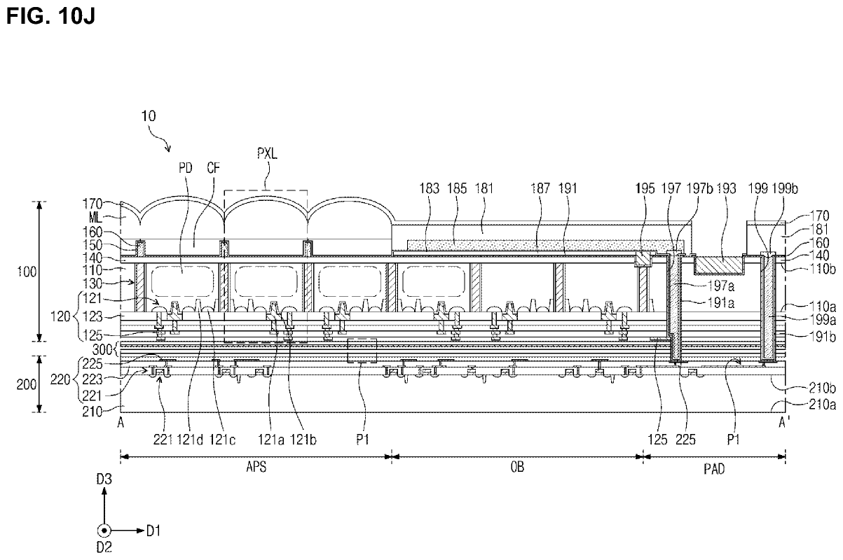

FIGS. 10A, 10B, 10C, 10D, 10E, 10F, 10G, 10H, 10I and 10J are cross-sectional views illustrating a method of fabricating an image sensor according to one or more example embodiments. According to one or more example embodiments, the formation of the structures illustrated in FIGS. 4B and 5A, from among various elements of the bonding portion, will be described as an example. However, it is to be understood that the method of fabricating an image sensor according to one or more example embodiments may be modified in various forms within the spirit and scope of one or more example embodiments.

Referring to FIG. 10A, a first chip 100, which may be a sensor chip, may be prepared. The first chip 100 may constitute a portion of a pixel.

To form the first chip 100, a first semiconductor substrate 110 may be prepared and some elements of a pixel PXL may be provided on a first surface 110a of the first semiconductor substrate 110. In the present operation, a first circuit interconnection layer 120 and a separation pattern 130 may be provided on the first surface 110a of the first semiconductor substrate 110. The separation pattern 130 may be provided by forming a trench and forming a first separation pattern and a second separation pattern in the trench. According to one or more example embodiments, the trench may be in the form of a recess having a predetermined depth from an upper surface of the first semiconductor substrate 110, and the first separation pattern and the second separation pattern may be provided in the trench.

A first circuit interconnection layer 120 may be provided on the first surface 110a of the first semiconductor substrate 110. The first circuit interconnection layer 120 may include a gate pattern 121a, a gate insulating pattern 121b, an impurity region 121c, and a device isolation pattern 121d. The first circuit interconnection layer 120 may be provided by forming a first circuit portion 121 and by forming first lower insulating layers 123 and a first conductive structure 125 on the first circuit portion 121.

Referring to FIG. 10B, a diffusion barrier layer DFB may be provided above the first surface 110a on which the first circuit interconnection layer 120 is provided. The diffusion barrier layer DFB may be formed of a material having a lower diffusion coefficient than hydrogen or deuterium, for example, an aluminum oxide (for example, alumina), a silicon carbon nitride, a silicon nitride, a zirconium oxide, a titanium oxide, a silicon oxide (for example, silicate), or a hafnium oxide, using atomic layer deposition (ALD). However, a method of forming the diffusion barrier layer DFB is not limited thereto, and, according to one or more example embodiments, the diffusion barrier layer DFB may be provided using various methods such as physical vapor deposition (PVD). The diffusion barrier layer DFB may be provided as a single layer, multiple layers, or a composite layer.

Referring to FIG. 10C, a first planarization layer 330a may be provided on the first surface 110a on which the diffusion barrier layer DFB is provided. The first planarization layer 330a may be formed of various insulating materials. In particular, the first planarization layer 330a may be formed of a silicon oxide, for example, silicate. In one or more example embodiments, the first planarization layer 330a may be formed of PE-TEOS.

Referring to FIG. 10D, a portion of an upper side of the first planarization layer 330a may be removed through a planarization process. In one or more example embodiments, the planarization process may be performed through chemical mechanical polishing (CMP). Then, a first bonding layer 310a may be provided on the first planarization layer 330a. The first bonding layer 310a may be formed of a silicon carbon nitride, a silicon oxide (for example, silicate), or a silicon nitride.

Referring to FIG. 10E, the first chip 100 on which the first bonding layer 310a is provided may be inverted and provided on the second chip 200 on which the second bonding layer 310b is provided.

The second chip 200 may be prepared separately from the first chip 100. The second chip 200 may be provided by preparing a second semiconductor substrate 210 and by forming a second circuit interconnection layer 220 on the second semiconductor substrate 210.

The second semiconductor substrate 210 may have a third surface 210a and a fourth surface 210b opposing the third surface 210a, and the second circuit interconnection layer 220 may be provided on the fourth surface 210b. The second circuit interconnection layer 220 may be provided by forming a second circuit portion 220 including a transistor and by forming second lower insulating layers 223 and a second conductive structure 225.

A second planarization layer 330b may be provided on the fourth surface 210b of the second semiconductor substrate 210 on which the second circuit interconnection layer 220 is provided. The second planarization layer 330b may be formed of various insulating materials. In particular, the second planarization layer 330b may be formed of a silicon oxide, for example, silicate. In one or more example embodiments, the second planarization layer 330b may be formed of PE-TEOS. Then, a portion of an upper side of the second planarization layer 330b may be removed through a planarization process. In one or more example embodiments, the planarization process may be performed through chemical mechanical polishing (CMP). Then, a second bonding layer 310b may be provided on the second planarization layer 330b. The second bonding layer 310b may be formed of a silicon carbon nitride, a silicon oxide (for example, silicate), or a silicon nitride, and may be formed of the same material as the first bonding layer 310a.

Next, the first chip 100 and the second chip 200 may be provided such that the first surface 110a and the fourth surface 210b face each other, allowing the first and second chips 100 and 200 to be bonded together.

Referring to FIG. 10F, the first bonding layer 310a of the first chip 100 and the second bonding layer 310b of the second chip 200 may be bonded through annealing. As a result, the first bonding layer 310a and the second bonding layer 310b may be connected and integrated with each other without being separated from each other.

Referring to FIG. 10G, after the first chip 100 and the second chip 200 are bonded to each other, a portion of the first semiconductor substrate 110 on a rear surface of the first chip 100, for example, a side of the second surface 110b, may be removed. A portion of the first semiconductor substrate 110 may be removed through chemical mechanical polishing (CMP). The CMP may be performed until the separation pattern 130 penetrates through opposite surfaces of the first semiconductor substrate 110, for example, until the first and second separation patterns 130 are exposed to the outside.

Referring to FIG. 10H, a hydrogen and/or deuterium treatment may be performed in a direction extending from the second surface 110b to the first surface 110a of the first semiconductor substrate 110. The hydrogen and/or deuterium treatment may be performed by high-pressure deuterium annealing at about 20 atmospheric pressure, atmospheric-pressure deuterium annealing (about 1 atmospheric pressure), or hydrogen annealing. In this case, a temperature of the annealing may be about 400 degrees Celsius or less, and the annealing may be performed at a temperature of about 250 degrees Celsius or less depending on a material. For example, a silicon nitride thin film may be deposited at a temperature of about 400 degrees Celsius or less. Even at a temperature of about 400 degrees Celsius or more, annealing may be performed depending on circumstances, but metal of a circuit interconnection is likely to be diffused. In the case of an aluminum oxide, annealing may be performed at a temperature of about 150 degrees Celsius to about 250 degrees Celsius, but embodiments are not limited thereto.

In this case, hydrogen and/or deuterium may permeate and diffuse into the first semiconductor substrate 110 by annealing (indicated by arrows), and the diffusion into the second chip 200 may be prevented by the diffusion barrier layer DFB.

Referring to FIG. 10I, the remaining elements of the pixel PXL may be provided on the first and second chips 100 and 200 treated with hydrogen and/or deuterium. For example, an upper insulating layer 140 may be provided on the second surface 110b treated with the hydrogen and/or deuterium, and a contact trench 195h for a contact plug 195, first and second through-holes 199, and the like, may be provided.

Referring to FIG. 10J, a color filter, a microlens ML, a bonding pad 193, and a contact plug 195 may be provided on a substrate on which an upper insulating layer 140, a contact trench 195h, and a first through-hole 197 and a second through-hole 199 are provided, and thus an image sensor may be completed.

As set forth above, according to one or more example embodiments, a diffusion barrier layer for preventing diffusion of hydrogen and/or deuterium may be provided in a bonding portion in a stack-type image sensor. Thus, the hydrogen and/or deuterium may be prevented from diffusing to elements in a logic chip to improve characteristics in a sensor chip, on which a photoelectric conversion sensor is provided, without deterioration of characteristics of the elements in the logic circuit. As a result, an image sensor having improved electrical characteristics may be provided.

While example embodiments have been particularly shown and described above, it will be apparent to those skilled in the art that modifications and variations could be made without departing from the spirit and scope of the present disclosure the following claims. For example, although formation of a diffusion barrier layer on a first passivation layer of a first chip has been described in the description of one or more example embodiments for the above-described fabricating method, the diffusion barrier layer may be provided on another layer and the fabricating method may be changed and modified within the scope of one or more example embodiments.

What is claimed is:

1. An image sensor comprising:
a first chip;
a second chip stacked on the first chip; and
a bonding portion provided between the first chip and the second chip,
wherein the first chip comprises:
a first semiconductor substrate comprising a first surface and a second surface opposing the first surface;
a photoelectric conversion region in the first semiconductor substrate; and
a first circuit interconnection layer provided on the first surface and adjacent to the photoelectric conversion region,
wherein the second chip comprises:
a second semiconductor substrate comprising a third surface and a fourth surface facing the first surface and opposing the third surface; and
a second circuit interconnection layer provided on the fourth surface, and
wherein the bonding portion comprises:
a bonding layer provided between the first circuit interconnection layer and the second circuit interconnection layer and configured to connect the first chip and the second chip; and
a diffusion barrier layer provided between the second circuit interconnection layer and the bonding layer and configured to inhibit diffusion of at least one of hydrogen or deuterium.

2. The image sensor of claim 1, wherein the diffusion barrier layer comprises at least one of an aluminum oxide, a silicon nitride, a zirconium oxide, a titanium oxide, or a hafnium oxide.

3. The image sensor of claim 2, further comprising:
a first passivation layer provided on the first circuit interconnection layer; and
a second passivation layer provided on the second circuit interconnection layer,
wherein the diffusion barrier layer is provided between at least one of (i) the first passivation layer and the bonding layer or (ii) the second passivation layer and the bonding layer.

4. The image sensor of claim 3, wherein the bonding layer comprises at least one of a silicon carbon nitride, a silicon nitride, or a silicon oxide.

5. The image sensor of claim 3, further comprising:
a first planarization layer provided between the first passivation layer and the bonding layer; and
a second planarization layer provided between the second passivation layer and the bonding layer.

6. The image sensor of claim 5, wherein the diffusion barrier layer is provided between at least one of (i) the first passivation layer and the first planarization layer, (ii) the first planarization layer and the bonding layer, (iii) the bonding layer and the second planarization layer, or (iv) the second planarization layer and the second passivation layer.

7. The image sensor of claim 6, further comprising:
a reflective layer provided between at least one of (i) the first passivation layer and the first planarization layer, (ii) the first planarization layer and the bonding layer, (iii) the bonding layer and the second planarization layer, or (iv) the second planarization layer and the second passivation layer.

8. The image sensor of claim 1, wherein the diffusion barrier layer comprises multiple layers.

9. The image sensor of claim 1, wherein the diffusion barrier layer comprises:
a first layer comprising a first material; and
a second layer comprises a second material different from the first material.

10. The image sensor of claim 9, wherein the first layer comprises a plurality of first layers and the second layer comprises a plurality of second layers, and
wherein the first layers and the second layers are alternately provided.

11. The image sensor of claim 1, wherein the diffusion barrier layer has a diffusion coefficient of 1.0×10⁻¹⁴ cm²/s or less.

12. The image sensor of claim 1, wherein the diffusion barrier layer has a thickness of 10 angstroms to 10,000 angstroms.

13. A method of fabricating an image sensor, the method comprising:
forming a portion of a pixel and a first circuit interconnection layer on a first semiconductor substrate comprising a first surface and a second surface opposing the first surface;
forming a second circuit interconnection layer on a second semiconductor substrate comprising a third surface and a fourth surface opposing the third surface;
forming a diffusion barrier layer on at least one of the first circuit interconnection layer or the second circuit interconnection layer;
forming a first bonding layer on the first circuit interconnection layer;
forming a second bonding layer on the second circuit interconnection layer;
providing the first surface to oppose the third surface and then connecting the first bonding layer and the second bonding layer;
planarizing the second surface;
performing at least one of a hydrogen treatment or a deuterium treatment in a direction extending from the second surface to the first surface; and
forming portions of the pixel, other than the portion of the pixel, on the second surface.

14. The method of claim 13, wherein the diffusion barrier layer comprises at least one of an aluminum oxide, a silicon nitride, a zirconium oxide, a titanium oxide, or a hafnium oxide.

15. The method of claim 13, wherein the forming the diffusion barrier layer is performed using atomic layer deposition.

16. The method of claim 13, wherein the performing the at least one of the hydrogen treatment or the deuterium treatment comprises at least one of high-pressure deuterium annealing, atmospheric-pressure deuterium annealing, or hydrogen annealing.

17. The method of claim 13, further comprising:
forming a first passivation layer on the first circuit interconnection layer; and
forming a second passivation layer on the second circuit interconnection layer.

18. The method of claim 17, further comprising:
forming a first planarization layer between the first passivation layer and the first bonding layer; and
forming a second planarization layer between the second passivation layer and the second bonding layer.

19. The method of claim 18, wherein the diffusion barrier layer is provided between at least one of (i) the first passivation layer and the first planarization layer, (ii) the first planarization layer and the connected first and second bonding layers, (iii) the connected first and second bonding layers and the second planarization layer, or (iv) the second planarization layer and the second passivation layer.

20. A method of fabricating an image sensor, the method comprising:
forming a first chip comprising a first semiconductor substrate and first elements of a pixel;
forming a second chip to control the first chip;
forming a diffusion barrier layer on at least one of an upper surface of the first chip or an upper surface of the second chip;
bonding the first chip and the second chip with the diffusion barrier layer interposed between the first chip and the second chip;
planarizing an external side surface of the first chip;
performing a hydrogen treatment or a deuterium treatment on the first chip in a direction extending from the first chip to the second chip; and
forming second elements of the pixel, which are different from the first elements of the pixel, on the external side surface of the first chip.
